(19) United States
(12) Patent Application Publication
(10) Pub. No.: US 2006/0078689 A1
(43) Pub. Date: Apr. 13, 2006

(54) EVAPORATION APPARATUS AND PROCESS

(76) Inventor: Kuo-Ching Chou, Taipei County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/906,097

(22) Filed: Feb. 3, 2005

(30) Foreign Application Priority Data
Oct. 13, 2004 (TW) 93130960

(51) Int. Cl. C23C 16/00; B05D 3/00

(52) U.S. Cl. 427/561; 427/248.1; 118/726

(57) ABSTRACT

An evaporation process applied to an evaporation apparatus to evaporate an evaporation source onto a substrate is provided. The evaporation apparatus comprises a purification chamber and an evaporation chamber, wherein a heating device is installed in the purification chamber and a deposition device is installed in the evaporation chamber. First, the evaporation source is supplied in the purification chamber, wherein impurities are formed on the surface of the evaporation source. Then, the evaporation source is heated by the heating device in order to gasify the impurities so they are reduced from the evaporation source. Next, the evaporation source is moved into the evaporation chamber and evaporated on the substrate by the deposition device. Thus, this evaporation process can reduce impurities before depositing the substrate and improve the yield factor of the evaporation process.

### BACKGROUND OF THE INVENTION

1. Field of the Invention

The present invention relates to an apparatus and process for depositing films. More particularly, the present invention relates to an evaporation apparatus and process.

2. Description of Related Art

In recent years, with the technology of optoelectronics and semiconductor process development, the technology of flat panel display has been progressed rapidly. Among various types of flat panel displays, plasma display has such advantages as big size, self-illuminance, wide-view angle, thinness and full colors, and thus has the potential of becoming the popular type of flat panel display in the next generation. The plasma display achieves the display function by utilizing the characteristics of the phosphor materials to irradiate by the ultraviolet light and then the visible light is emitted. The illuminant structure of the plasma display mainly comprises a couple of electrodes (i.e. scan electrode and sustain electrode), discharging gases and a phosphor-material layer. When the voltage between the two electrodes exceeds over a threshold value, the discharging gases will be discharged and emit the ultraviolet light. After the phosphor-material layer is irradiated by ultraviolet light, the phosphor-materials of the phosphor-material layer will be excited to an excited state. When the phosphor-materials go from the excited state to a ground state, the phosphor-materials will then emit visible light with different colors according to the characteristics of different materials.

It should be noted that the scan electrode and the sustain electrode are usually covered with a dielectric layer. The dielectric layer is covered with a passivation layer, which is usually made of magnesium oxide. When the discharging gases are discharged, the passivation layer is used to protect the dielectric layer and the electrodes from being damaged by charged particles. The magnesium oxide has the characteristic of low work function, and thus the charged particles are prone to have the second collision with the passivation layer. Therefore, the plasma production can be improved by gas discharged. In the conventional plasma display manufacturing process, the passivation layer, which is made of magnesium oxide, is formed during the evaporation process.

FIG. 1 is a schematic drawing of the conventional evaporation apparatus. Referring to FIG. 1, the conventional evaporation apparatus 100 comprises an evaporation chamber 110, which comprises a substrate 120, a feeder 122, a deposition device 126 and a vacuum device 128. The vacuum of the evaporation chamber 110 is maintained by the vacuum device 128. The deposition device 126 comprises a hearth 126a and an electron gun 126b. The Magnesium oxide 150 is placed in the hearth 126a and serves as an evaporation source. An electron beam 160, provided by the electron gun 126b, then heats up the Magnesium oxide 150 to evaporate and deposit on the substrate 120. The feeder 122 is filled with full amount of Magnesium oxide 150 to make sure that it is supplied onto the hearth 126a continuously and the shortage of the Magnesium oxide 150 during the evaporation process will not occur.

It should be noted that the Magnesium oxide 150 is usually filled in the feeder 122 during the periodical maintenance of the evaporation apparatus. During the process of feeding Magnesium oxide 150 into feeder 122, it is unavoidable that Magnesium oxide 150 will be exposed in the air. As a result, the surface of the Magnesium oxide 150 may absorb carbon dioxide (CO₂), water (H₂O) or nitrogen (N₂), etc. in the air. Further, the surface of Magnesium oxide 150 may form a layer of magnesium carbonate (MgCO₃) or magnesium hydroxide (Mg (OH)₂), etc. Accordingly, during an evaporation process, when bombarded by the electron beam 160, the magnesium carbonate (MgCO₃) or magnesium hydroxide (Mg (OH)₂) would be decomposed into carbon dioxide, carbon oxide, water, hydrogen gas and nitrogen gas by electron beam bombardment. As a result, the Magnesium oxide 150 is oxidized and thus the colorless impurities are formed, the passivation layer of Magnesium oxide (not shown) deposited on the substrate 120 would have excessive carbon and impurities. Therefore, the passivation layer on the substrate 120, i.e., the Magnesium oxide layer (not shown), will be polluted and mixed with the above-mentioned pollutant during the filming process. The polluted Magnesium oxide layer (not shown) may result in an unstable firing voltage in the discharged space, thus deteriorating the discharge function of the plasma display panel.

### SUMMARY OF THE INVENTION

Accordingly, the present invention is directed to provide an evaporation apparatus to reduce the impurities of the evaporation source before being evaporated and to provide better quality of film deposition.

Another object of the present invention is to provide an evaporation process to reduce the impurities of the evaporation source before being evaporated and to provide better quality of film deposition.

In order to achieve the objectives as described above, the present invention discloses an evaporation apparatus applied for evaporating an evaporation source onto a substrate. According to one embodiment of the present invention, the evaporation apparatus comprises a purification chamber, an evaporation chamber, a heating device, and a deposition device. The evaporation chamber is connected to the purification chamber. The heating device is installed inside the purification chamber and is adapted for heating and purifying the evaporation source. The deposition device, installed inside the evaporation chamber, is used to evaporate the purified evaporation source onto the substrate.

In order to achieve the objectives as described above, the present invention discloses an evaporation process applied for an evaporation apparatus, wherein the evaporation apparatus comprises a purification chamber and an evaporation chamber. First, the evaporation process is provided by providing an evaporation source inside the purification chamber, wherein the impurities are formed on the surface of the evaporation source. Next, evaporation source is heated to gasify the impurities so as to reduce them from the evaporation source. And then, the evaporation source is moved into the evaporation chamber to be evaporated onto the substrate.

The present invention provides an evaporation apparatus and process, wherein the evaporation apparatus has the purification chamber to purify the evaporation source before evaporating the evaporation source onto the substrate and to reduce the impurities of the evaporation source formed during its reaction with the outside. Therefore, the evaporation apparatus and process in the present invention is directed to effectively prevent the film on the substrate from being polluted by the impurities, so the quality of the evaporation process can be promoted and a more stable firing voltage can be achieved to eventually improve the discharging functions of the plasma display panels.

### BRIEF DESCRIPTION OF THE DRAWINGS

The accompanying drawings are included to provide a better understanding of the invention, and are incorporated in and constitute a part of this specification. The drawings illustrate embodiments of the invention, and together with the description, serve to explain the principles of the invention.

FIG. 1 is a schematic drawing of a conventional evaporation apparatus.

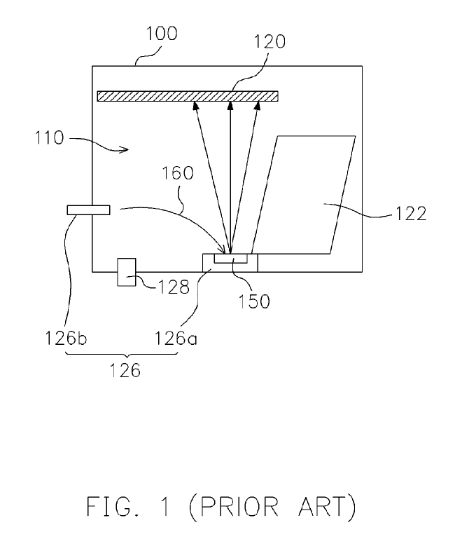

FIG. 2 is a schematic drawing of an evaporation apparatus in accordance with a preferred embodiment of the present invention.

FIG. 3 is a flowchart depicting an evaporation process in accordance with a preferred embodiment of the present invention.

### DESCRIPTION OF THE PREFERRED EMBODIMENTS

Various specific embodiments of the present invention are disclosed below, illustrating examples of various possible implementations of the concepts of the present invention. The following description is made for the purpose of illustrating the general principles of the invention and should not be taken in a limiting sense. The scope of the invention is best determined by reference to the appended claims.

To avoid the film from being polluted by the impurities on the evaporation source, the present invention has added a purification chamber inside the evaporation apparatus, wherein the evaporation source is purified in the purification chamber to reduce the impurities of the evaporation source before being evaporated.

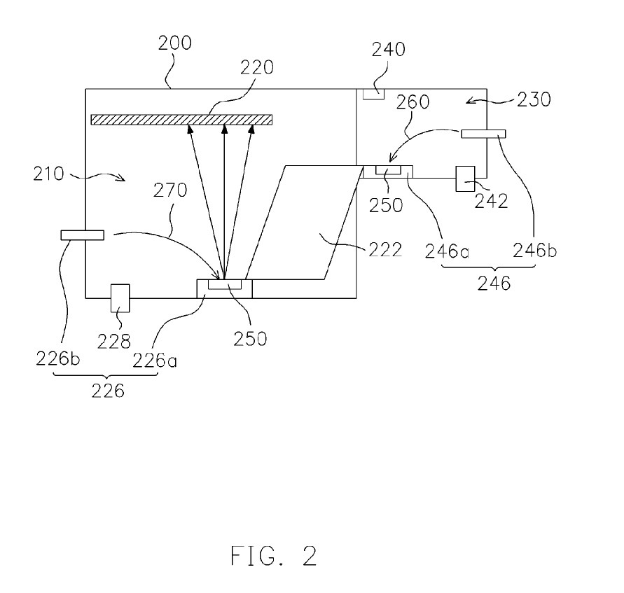

FIG. 2 is a schematic drawing of an evaporation apparatus in accordance with a preferred embodiment of the present invention. Referring to FIG. 2, it shows an evaporation apparatus 200 applied to the evaporation process of the plasma display apparatus to form a passivation layer, i.e. magnesium oxide layer, on the front substrate 220 of the plasma display apparatus. The evaporation apparatus 200 comprises an evaporation chamber 210 and a purification chamber 230, which are neighboring. The purification chamber 230 comprises therein a monitor device 240, an exhaust device 242 and a heating device 246 composed of a first hearth 246a and a first electron gun 246b. The first hearth 246a is made of temperature-resistant material, such as wolfram (W), molybdenum (Mo), or tantalum (Ta), and is used to store the evaporation source 250, such as magnesium oxide. The evaporation source 250 will be reacted with the air before entering in the purification chamber 230 and the surface of the evaporation source 250 may absorb gases in the air, such as carbon dioxide(CO₂), water(H₂O) or nitrogen(N₂) and may form such impurities as magnesium carbonate(MgCO₃) and magnesium hydroxide(Mg(OH)₂). In solution, the first electron gun 246b provides an electron beam 260 to the evaporation source 250 in the first hearth 246a to heat and gasify the impurities of the evaporation source 250, and thus purifies the evaporation source 250. For example, the magnesium carbonate (MgCO₃) or magnesium hydroxide (Mg(OH)₂) will be decomposed into magnesium oxide, carbon dioxide and moisture by the electron beam 260 heated up over 400° C. The exhaust device 242 is used to exhaust the gases such as carbon dioxide and moisture in purification chamber 230 to the outside. The monitor device 240 is a residual gas analyzer that measures the partial pressure of the purification chamber 230 to monitor the residual of the gas. When the partial gas pressure measured by the monitor device 240 is in a steady condition, the impure gas such as carbon dioxide and moisture has been exhausted from the exhaust device 242 and the purified evaporation source 250 can be obtained.

Referring to FIG. 2, the evaporation chamber 210 is equipped with a feeder 222, a vacuum device 228, and a deposition device 226 composed of a second hearth 226a and a second electron gun 226b. The substrate 220 lies on top of the second hearth 226a, which is made of temperature-resistant material, such as wolfram (W), molybdenum (Mo), or tantalum (Ta). The second hearth 226a stores therein the purified evaporation source 250. The second electron gun 226b provides an electron beam 270 to the evaporation source 250 in the second hearth 226a to heat up the evaporation source 250 over 2000° C. and to evaporate the evaporation source 250 onto the substrate 220, and then the magnesium oxide layer is formed thereon. The vacuum device 228 is used to maintain the vacuum level of the evaporation chamber 210. The feeder 222 connects the heating device 246 with the deposition device 226, and forwards the evaporation source 250 purified by the heating device 246 to the deposition device 226.

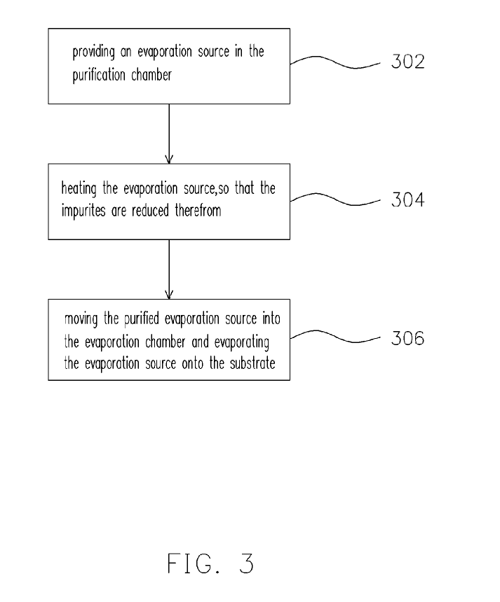

To elaborate on the characteristic of the present invention, the following is an explanation of the evaporation process in connection with above-mentioned evaporation apparatus. Please refer to FIGS. 2 and 3. FIG. 3 depicts a flowchart of the evaporation process according to a preferred embodiment of the present invention.

The process starts by feeding the evaporation source 250 into the purification chamber 230 (step 302). The best timing is that when the evaporation source 250 is loaded in the first hearth 246a during the periodical maintenance of the evaporation apparatus 200.

Next, the evaporation source 250 is heated to reduce the impurities thereof (step 304). The first electron gun 246b provides a plurality of electron beams to the evaporation source 250, and the impurities thereof are then gasified and reduced from the evaporation source 250. It should be mentioned that the work temperature of the heating process should be kept lower than that of the evaporating process so as to prevent the evaporation source 250 from over-evaporation and waste. In addition, the exhaust device 242 is used to exhaust the gasified impurities outside of the purification chamber 230 during the process. The monitor device 240 further monitors the amount of the gasified impurities in the purification chamber 230 to reflect the purified level of evaporation source 250.

And then, the purified evaporation source 250 is moved to the evaporation chamber 210 to be evaporated onto the substrate 220 (step 306). The feeder 222 is filled with the evaporation source 250, which is sent to the second hearth 226a continuously during evaporation. The second electron gun 226b then provides an electron beam to the evaporation source 250 on the second hearth 226a to form the magnesium oxide layer on substrate 220 (not shown).

It should be noted that the heating device of the present invention is not limited to the electron gun described above; it can be a thermal coupler or other heating device that can also be used to heat up the evaporation source to achieve purification or film deposition mentioned above. In addition, although the embodiment of the present invention only refers to the magnesium oxide layer of the plasma display apparatus, persons skilled in the art can apply this evaporation apparatus and process to other deposition processes to promote the yield factor of the processes.

To sum up, the present invention is directed to provide the evaporation apparatus and process to purify the evaporation source and reduce the impurities thereof before evaporating the evaporation source on the substrate. Therefore, the present invention, the evaporation apparatus and process, can effectively prevent the evaporated film on the substrate from being polluted by the impurities to maintain the characteristic of the evaporated film and further promote the yield factor of the evaporation process.

The above description provides a full and complete description of the preferred embodiments of the present invention. Various modifications, alternate construction, and equivalent may be made by those skilled in the art without changing the scope or spirit of the invention. Accordingly, the above description and illustrations should not be construed as limiting the scope of the invention which is defined by the following claims.

What is claimed is:

1. An evaporation apparatus applied for evaporating an evaporation source on a substrate, comprising:
a purification chamber;
an evaporation chamber connected to the purification chamber;
a heating device installed inside the purification chamber and adapted for heating and purifying the evaporation source; and
a deposition device installed in the evaporation chamber to evaporate the purified evaporation source on the substrate.

2. The evaporation apparatus of claim 1, further comprising an exhaust device installed in the purification chamber.

3. The evaporation apparatus of claim 1, wherein the heating device comprising a thermal coupler or an electron gun.

4. The evaporation apparatus of claim 1, further comprising a feeder, installed in the evaporation chamber and connecting the heating device with the deposition device, to store the purified evaporation source and forward the purified evaporation source to the deposition device.

5. The evaporation apparatus of claim 1, further comprising a monitor device installed in the purification chamber.

6. The evaporation apparatus of claim 5, wherein the monitor device comprising a residual gas analyzer.

7. An evaporation process applied to an evaporation apparatus, wherein the evaporation apparatus has a purification chamber and an evaporation chamber, and the evaporation process comprising:
providing an evaporation source in the purification chamber, wherein impurities are formed on a surface of the evaporation source;
heating the evaporation source so that the impurities are gasified and reduced from the evaporation source; and
moving the evaporation source into the evaporation chamber and evaporating the evaporation source on the substrate.

8. The evaporation process of claim 7, wherein the gasified impurities are exhausted outside while gasified and reduced from the evaporation source.

9. The evaporation process of claim 7, wherein the heating of the evaporation source can be achieved by a thermal coupler or an electron gun.

10. The evaporation process of claim 7, wherein the amount of the gasified impurities is monitored in the purification chamber while the evaporation source is heated.

11. The evaporation process of claim 7, wherein the work temperature when heating the evaporation source is kept lower than that when evaporating the evaporation source.
